(19) United States
(12) Patent Application Publication
(10) Pub. No.: US 2023/0045674 A1
(43) Pub. Date: Feb. 9, 2023

(54) SEMICONDUCTOR DEVICE

(71) Applicant: Samsung Electronics Co., Ltd., Suwon-si (KR)

(72) Inventors: Hyeon-Woo Jang, Hwaseong-si (KR); Dong-Wan Kim, Hwaseong-si (KR); Keonhee Park, Suwon-si (KR); Dong-Sik Park, Suwon-si (KR); Joonsuk Park, Suwon-si (KR); Jihoon Chang, Yongin-si (KR)

(21) Appl. No.: 17/662,306

(22) Filed: May 6, 2022

(30) Foreign Application Priority Data
Aug. 5, 2021 (KR) 10-2021-0103233

(51) Int. Cl. H01L 27/108

(52) U.S. Cl. CPC H01L 27/10897; H01L 27/10814; H01L 27/10823; H01L 27/10855; H01L 27/10885; H01L 27/10894

(57) ABSTRACT

A semiconductor device may include a substrate including a cell region and a peripheral region, a gate stack on the peripheral region, an interlayer insulating layer on the gate stack, peripheral circuit interconnection lines on the interlayer insulating layer, and an interconnection insulating pattern between the peripheral circuit interconnection lines. The interconnection insulating pattern may include a pair of vertical portions spaced apart from each other in a first direction parallel to a top surface of the substrate and a connecting portion connecting the vertical portions to each other. Each of the vertical portions of the interconnection insulating pattern may have a first thickness at a same level as top surfaces of the peripheral circuit interconnection lines and a second thickness at a same level as bottom surfaces of the peripheral circuit interconnection lines. The first thickness may be substantially equal to the second thickness.

### CROSS-REFERENCE TO RELATED APPLICATIONS

This U.S. non-provisional patent application claims priority under 35 U.S.C. § 119 to Korean Patent Application No. 10-2021-0103233, filed on Aug. 5, 2021, in the Korean Intellectual Property Office, the entire contents of which are hereby incorporated by reference.

### BACKGROUND

The present disclosure relates to a semiconductor device, and in particular, to a semiconductor device including an insulating pattern between peripheral circuit interconnection lines on a peripheral region.

Due to their small-size, multifunctional, and/or low-cost characteristics, semiconductor devices are being esteemed as important elements in the electronics industry. The semiconductor devices may be classified into semiconductor memory devices for storing data, semiconductor logic devices for processing data, and hybrid semiconductor devices including both memory and logic elements.

In general, semiconductor devices may include patterns, which are vertically stacked, and contact plugs, which are used to electrically connect the patterns to each other. As an integration density of semiconductor devices increases, distances between the patterns and/or between the pattern and the contact plug decrease. Thus, a parasitic capacitance between the patterns and/or between the pattern and the contact plug increases, and this may lead to deterioration in performance or operation speed of semiconductor devices.

### SUMMARY

Some embodiments of the inventive concept may provide a semiconductor device with improved electrical characteristics.

According to an embodiment of the inventive concept, a semiconductor device may include a substrate including a cell region and a peripheral region, a gate stack on the peripheral region, an interlayer insulating layer on the gate stack, peripheral circuit interconnection lines on the interlayer insulating layer, and an interconnection insulating pattern between the peripheral circuit interconnection lines. The interconnection insulating pattern may include a pair of vertical portions, which are spaced apart from each other in a first direction parallel to a top surface of the substrate, and a connecting portion, which is connects the vertical portions to each other. Each of the vertical portions of the interconnection insulating pattern may have a first thickness in the first direction at a same level as top surfaces of the peripheral circuit interconnection lines and a second thickness in the first direction at a same level as bottom surfaces of the peripheral circuit interconnection lines. The first thickness may be substantially equal to the second thickness.

According to an embodiment of the inventive concept, a semiconductor device may include a substrate including a cell region and a peripheral region, the peripheral region including active regions and a device isolation layer defining the active regions, gate stacks on the active region, an interlayer insulating layer on the gate stack, the interlayer insulating layer including a first trench, and peripheral circuit interconnection lines on the interlayer insulating layer and a first interconnection insulating pattern between the peripheral circuit interconnection lines. The first interconnection insulating pattern may be in a portion of the first trench. The first interconnection insulating pattern may overlap the device isolation layer in a direction perpendicular to a top surface of the substrate, and the topmost surface of the first interconnection insulating pattern may be coplanar with a top surface of one of the peripheral circuit interconnection lines adjacent thereto.

According to an embodiment of the inventive concept, a semiconductor device may include a substrate including a cell region and a peripheral region, the cell region including first active regions and a first device isolation layer defining the first active regions, the peripheral region including second active regions and a second device isolation layer defining the second active region, word lines that extend in a first direction to cross the first active regions, bit line structures provided on the word lines that extend in a second direction perpendicular to the first direction, spacer structures on side surfaces of the bit line structures, a lower contact between the spacer structures and connected to the first active region, a landing pad on the lower contact that extends to a region on top surfaces of the bit line structures, the landing pad including a pad metal pattern and a barrier layer between the pad metal pattern and the lower contact, an insulating pattern at least partially enclosing a side surface of the landing pad, a top surface of the insulating pattern being coplanar with the landing pad, a capacitor on a top surface of the landing pad, gate stacks on the second active region, gate spacer structures on side surfaces of each of the gate stacks, a peripheral contact between the gate spacer structures and connected to the second active region, a first interlayer insulating layer on and at least partially covering side surfaces of the gate spacer structures while top surfaces of the gate spacer structures remain free of the first interlayer insulating layer, a second interlayer insulating layer on the gate stack and the first interlayer insulating layer, peripheral circuit interconnection lines, which are on the first interlayer insulating layer and connected to the peripheral contact, and an interconnection insulating pattern between the peripheral circuit interconnection lines. The interconnection insulating pattern may include a pair of vertical portions, which are spaced apart from each other in a first direction parallel to a top surface of the substrate, and a connecting portion, which connects the vertical portions to each other. Each of the vertical portions of the interconnection insulating pattern may have a first thickness at a same level as top surfaces of the peripheral circuit interconnection lines and a second thickness at a same level as bottom surfaces of the peripheral circuit interconnection lines. The connecting portion may have a third thickness in a direction perpendicular to the top surface of the substrate, and the third thickness may be equal to or greater than the first thickness and the second thickness.

### BRIEF DESCRIPTION OF THE DRAWINGS

FIG. 1 is a plan view schematically illustrating a portion of a semiconductor device according to an embodiment of the inventive concept.

FIG. 2 is a plan view illustrating a portion of a semiconductor device according to an embodiment of the inventive concept.

FIG. 3 is a sectional view taken along lines A-A′, B-B′, and C-C′ of FIG. 2.

FIG. 4 is an enlarged sectional view illustrating a portion ‘aa’ of FIG. 3.

FIG. 5 is an enlarged sectional view illustrating a portion of a semiconductor device, which corresponds to the portion ‘aa’ of FIG. 3, according to a comparative example.

FIGS. 6A to 6R are sectional views, which are taken along the lines A-A′ and C-C′ of FIG. 2 to illustrate a method of fabricating a semiconductor device according to an embodiment of the inventive concept.

### DETAILED DESCRIPTION

Example embodiments of the inventive concepts will now be described more fully with reference to the accompanying drawings, in which example embodiments are shown. Identical reference numerals are used for the same constituent elements in the drawings, and duplicate descriptions thereof are omitted. It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

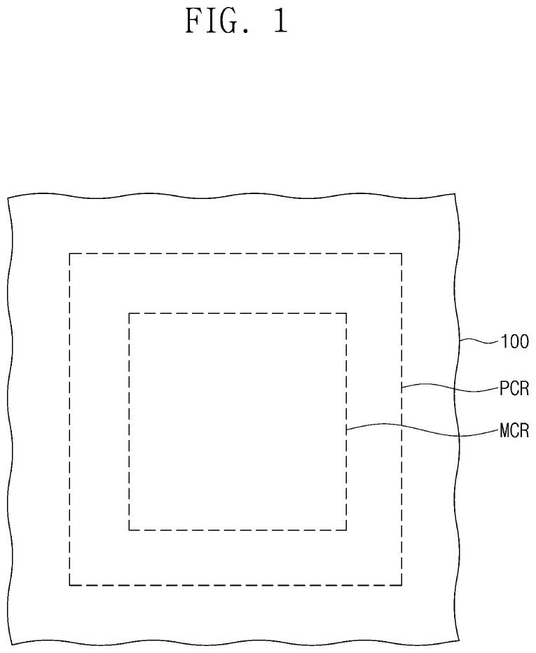

FIG. 1 is a plan view schematically illustrating a portion of a semiconductor device according to an embodiment of the inventive concept.

A semiconductor device according to an embodiment of the inventive concept may include a substrate 100 with a cell region MCR and a peripheral region PCR. The cell region MCR may include a plurality of memory cells. The cell region MCR may include at memory cells of volatile memory devices, memory cells of nonvolatile memory devices, or memory cells of both volatile and nonvolatile memory devices. In an embodiment, the cell region MCR may be a memory cell region of a dynamic random access memory (DRAM) device. The cell region MCR may include a plurality of unit memory cells, which are used to store data. Each of the unit memory cells may include at least one transistor and at least one capacitor.

The peripheral region PCR may be provided adjacent to the cell region MCR. In an embodiment, the peripheral region PCR may be provided near at least one side of the cell region MCR. For example, the peripheral region PCR may be provided to at least partially enclose the cell region MCR. A device isolation layer may be provided between the cell region MCR and the peripheral region PCR to separate the cell region MCR from the peripheral region PCR.

The peripheral region PCR may include circuits, which are used to drive the cell region MCR. In an embodiment, the peripheral region PCR may include a core region of a DRAM device. The core region may include, for example, a sense amplifier and a write driver. In an embodiment, the peripheral region PCR may include a peripheral circuit region of the DRAM device. The peripheral circuit region may include, for example, a row decoder and a column decoder.

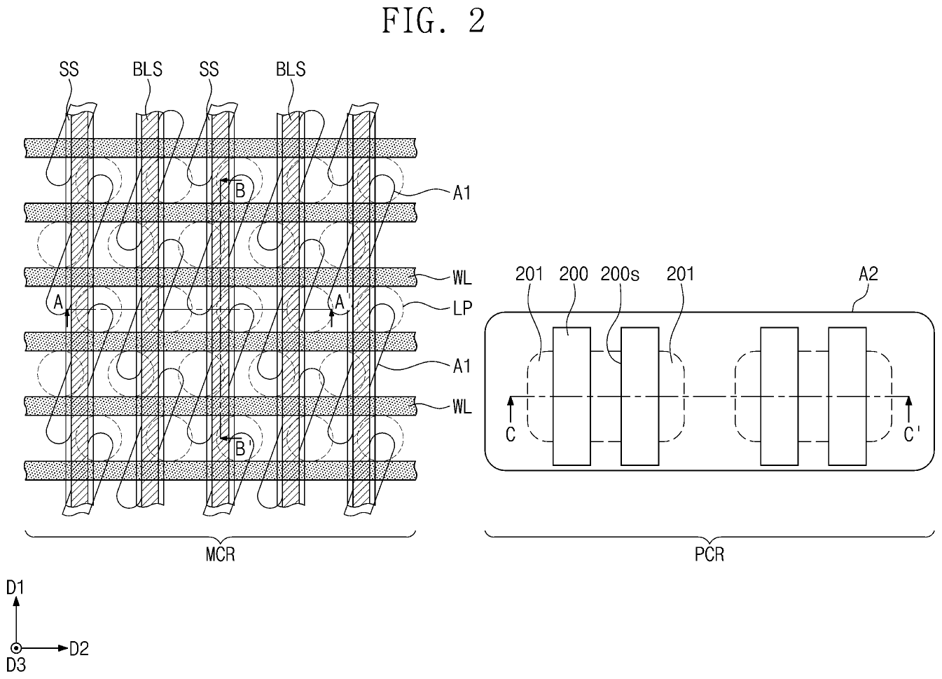

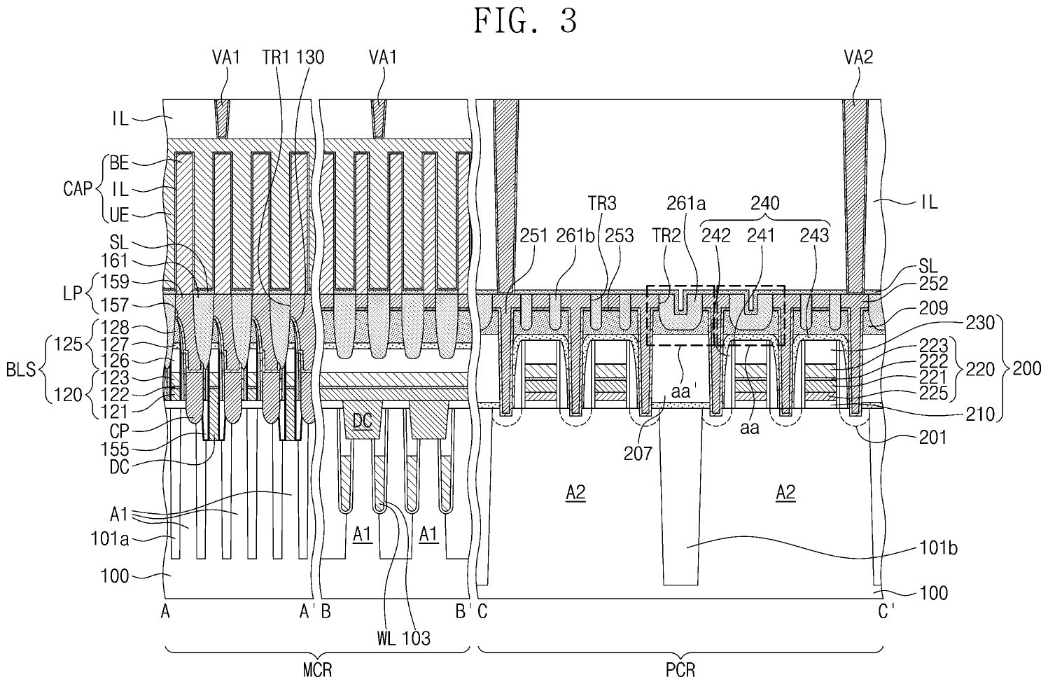

FIG. 2 is a plan view illustrating portions (e.g., a portion of a cell region and a portion of a peripheral region) of a semiconductor device according to an embodiment of the inventive concept. FIG. 3 is a sectional view taken along lines A-A′, B-B′, and C-C′ of FIG. 2.

Referring to FIGS. 2 and 3, a first device isolation layer 101a may be on the cell region MCR of the substrate 100 to define first active regions A1. The substrate 100 may be a semiconductor substrate, which is formed of or includes silicon, germanium, or silicon-germanium.

The first active regions A1 may be in an upper portion of the substrate 100. The first active regions A1 may be formed by patterning an upper portion of the substrate 100. The first active regions A1 may have a rectangular or bar shape. The first active regions A1 may be two-dimensionally arranged in a first direction D1 and a second direction D2. The first active regions A1 may have a long axis that is inclined to the first and second directions D1 and D2. Each of the first active regions A1 may have a decreasing width as a distance from a bottom surface of the substrate 100 increases. In other words, each of the first active regions A1 may have a decreasing width in a direction perpendicular to a top surface of the substrate 100 (i.e., in a third direction D3).

Word lines WL may be in the substrate 100. The word lines WL may extend in the first direction D2 to cross the first active regions A1 and the first device isolation layer 101a, when viewed in a plan view. The word lines WL may be arranged in the second direction D1. A gate insulating layer 103 may be interposed between the word lines WL and the substrate 100.

In detail, gate recess regions 102 may be formed in the first active regions A1 and the first device isolation layer 101a. The gate insulating layer 103 may conformally at least partially cover inner surfaces of the gate recess regions 102. The word lines WL may be in and at least partially fill lower portions of the gate recess regions 102. The word lines WL may be spaced apart from the first active regions A1 and the first device isolation layer 101a with the gate insulating layer 103 interposed therebetween. Top surfaces of the word lines WL may be located at a level lower than the top surface of the substrate 100 as shown in the cross-sectional view of FIG. 3. Hard mask patterns 105 may be on the top surfaces of the word lines WL to be in and at least partially fill remaining portions of the gate recess regions 102. A top surface of the hard mask pattern 105 may be located at the same level as the top surface of the substrate 100.

Bit line structures BLS may extend in the first direction D1 to cross the first active regions A1. The bit line structures BLS may be electrically disconnected from the word lines WL to cross the word lines WL. The bit line structure BLS may include a bit line 120 and a bit line capping pattern 125 on the bit line 120.

The bit line 120 may include a polysilicon pattern 121, a silicide pattern 122, and a metal pattern 123, which are sequentially stacked. A lower insulating layer 110 may be interposed between the polysilicon pattern 121 and the substrate 100, and a portion of the polysilicon pattern 121 (hereinafter, a bit line contact pattern DC) may be in physical contact with the first active region A1. In other words, the bit line 120 may be electrically connected to the first active region A1 through the bit line contact pattern DC. A bottom surface of the bit line contact pattern DC may be located at a level which is lower than the top surface of the substrate 100 and is higher than the top surfaces of the word lines WL as shown in the cross-sectional view of FIG. 3. The bit line contact pattern DC may be locally disposed in a recess region, which is formed in the substrate 100 to expose a top surface of the first active region A1. The recess region may have an elliptical shape, when viewed in a plan view, and a width of the recess region in a short axis direction may be greater than a width of the bit line structure BLS.

The bit line capping pattern 125 may be on the metal pattern 123 of the bit line 120. The bit line capping pattern 125 may include a first capping pattern 126, a second capping pattern 127, and a third capping pattern 128.

A bit line contact spacer 155 may be provided to be in and fill at least a portion of a remaining portion of the recess region provided with the bit line contact pattern DC. As an example, the bit line contact spacer 155 may be on and at least partially cover opposite side surfaces of the bit line contact pattern DC. As another example, the bit line contact spacer 155 may be provided in the recess region to at least partially enclose the bit line contact pattern DC. The bit line contact spacer 155 may be formed of or include an insulating material having an etch selectivity with respect to the lower insulating layer 110. For example, the bit line contact spacer 155 may be formed of or include one or more materials, such as, but not limited to, silicon oxide, silicon nitride, and/or silicon oxynitride and may have a multi-layered structure. In an embodiment, a top surface of the bit line contact spacer 155 may be located at substantially the same level as a top surface of the lower insulating layer 110.

Lower contacts CP may be disposed between side surfaces of the bit line structures BLS. The lower contacts CP may be arranged along the side surfaces of the bit line structures BLS and in the first direction D1. Each of the lower contacts CP may be between the word lines WL and between the bit line structures BLS, when viewed in a plan view. Each of the lower contacts CP may be coupled to the substrate 100, between two adjacent ones of the bit lines 120. The lower contact CP may be electrically connected to the first active region A1 of the substrate 100. The lower contact CP may be formed of or include, for example, doped polysilicon.

A bottom end of the lower contact CP may be located at a level that is lower than the top surface of the substrate 100 and is higher than the bottom surface of the bit line contact pattern DC as shown in the cross-sectional view of FIG. 3. A top surface of the lower contact CP may be located at a level lower than a bottom surface of the bit line capping pattern 125 of the bit line structure BLS as shown in the cross-sectional view of FIG. 3. The lower contact CP may be electrically disconnected from the bit line contact pattern DC by a bit line contact spacer 155.

A landing pad LP may be on the lower contact CP. The landing pad LP may be electrically connected to the first active region A1 of the substrate 100 through the lower contact CP. A top surface of the landing pad LP may be located at a level higher than top surfaces of the bit line structures BLS, and a bottom surface of the landing pad LP may be located at a level lower than the top surfaces of the bit line structures BLS as shown in the cross-sectional view of FIG. 3. For example, the bottom surface of the landing pad LP may be located at a level lower than a top surface of the metal pattern 123 of the bit line 120 as shown in the cross-sectional view of FIG. 3. The landing pad LP may include a barrier layer 157 and a pad metal pattern 159, which are sequentially stacked. In an embodiment, a contact silicide pattern may be provided between the lower contact CP and the landing pad LP.

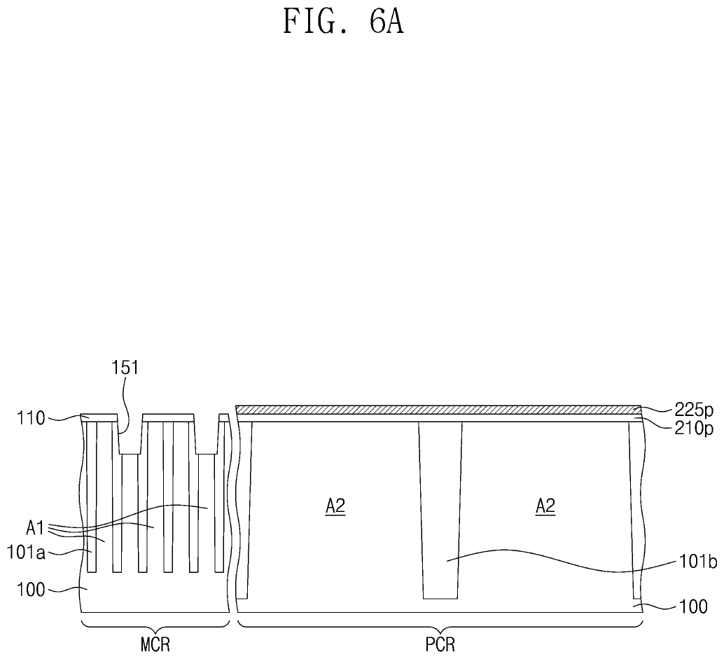

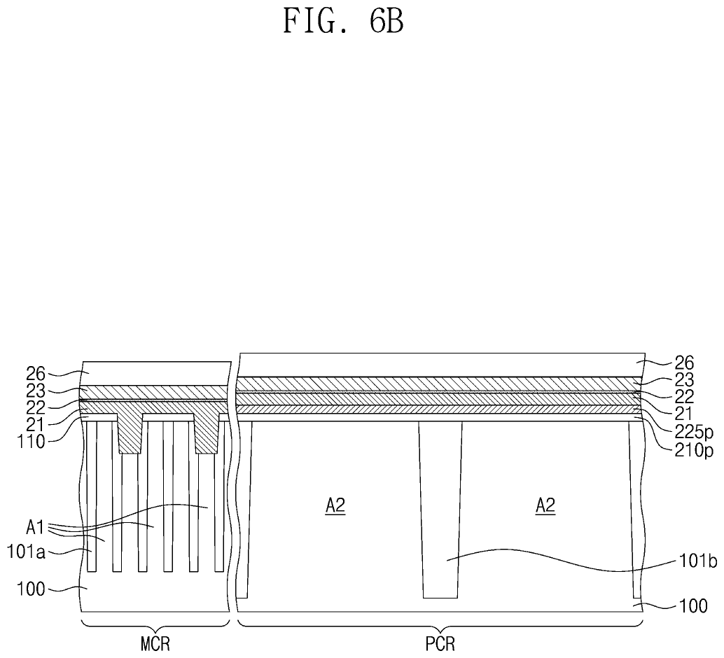

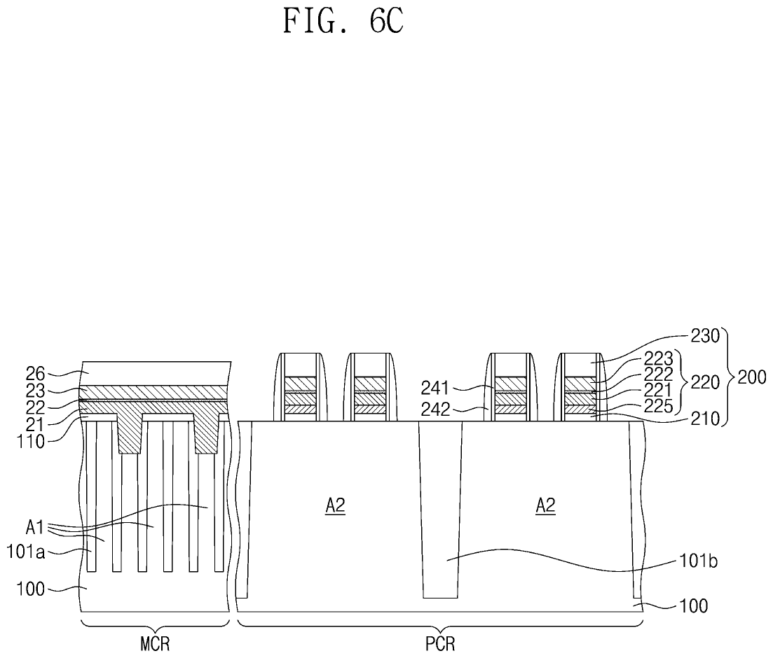

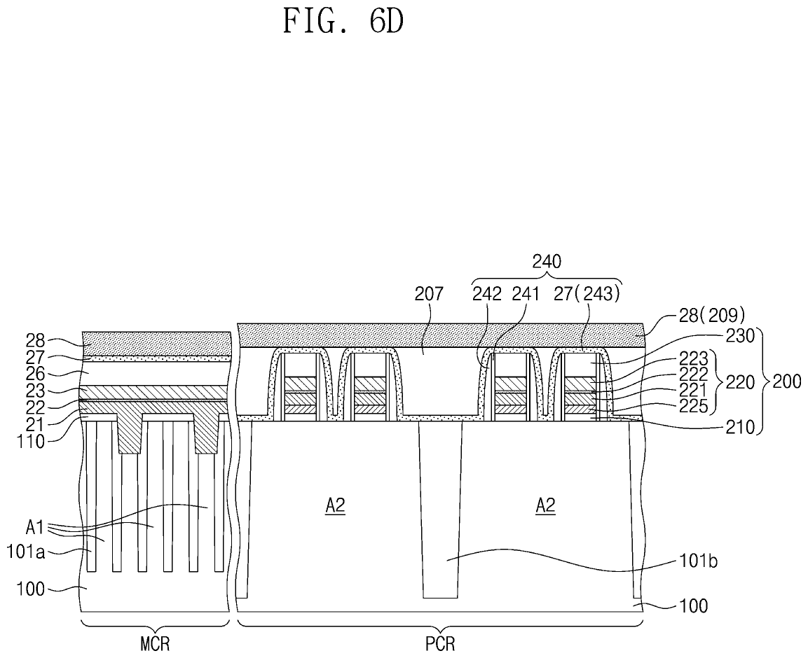

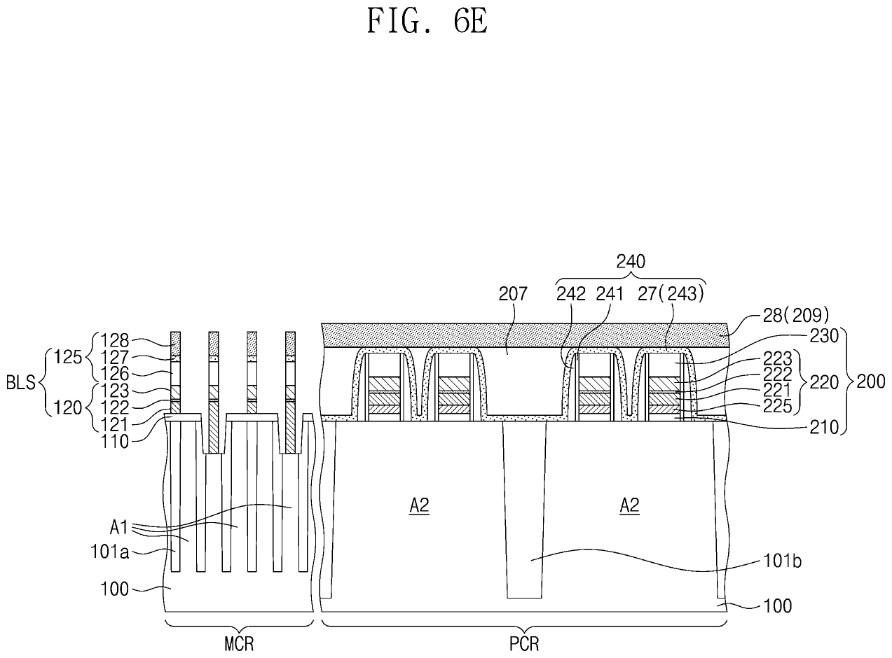

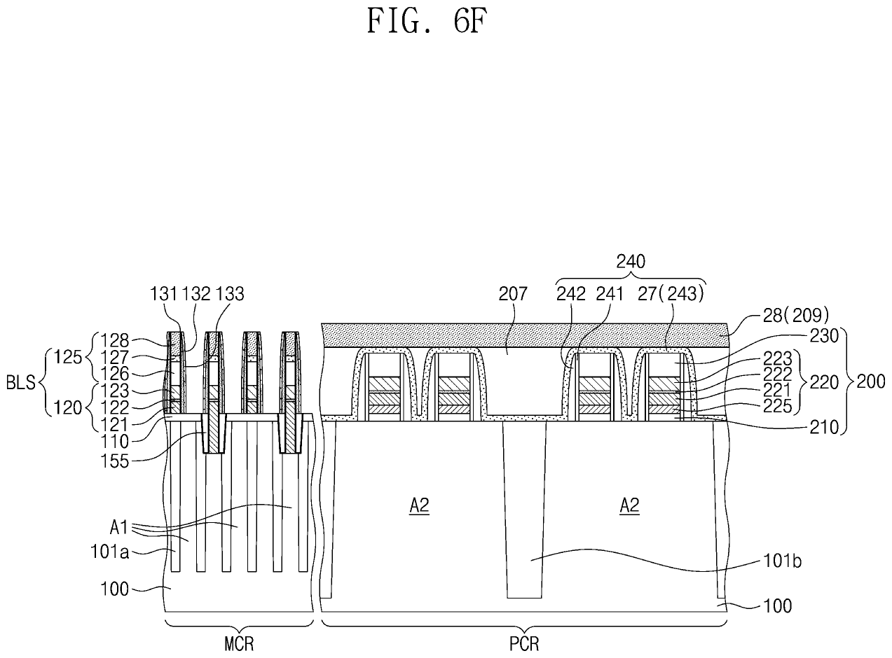

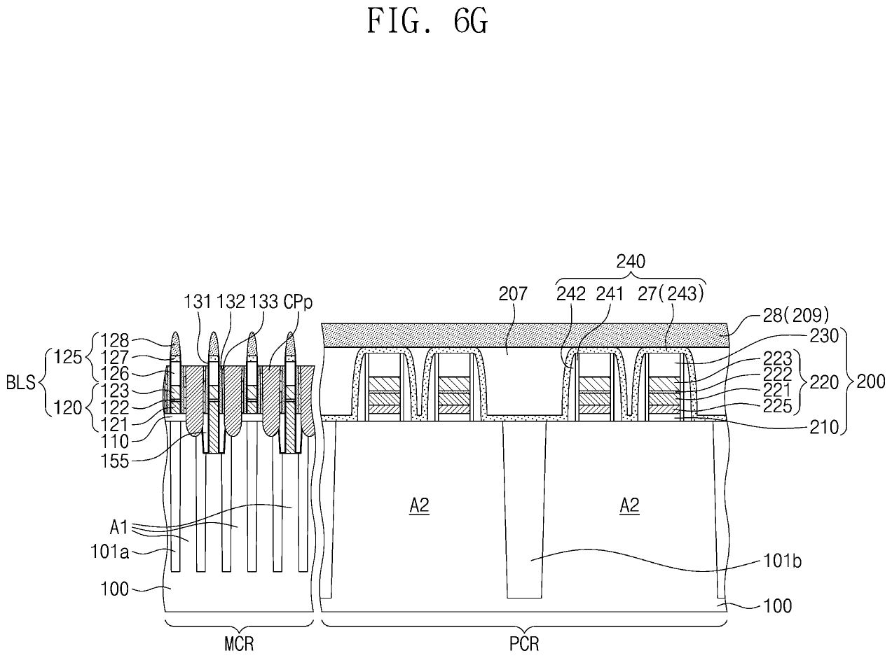

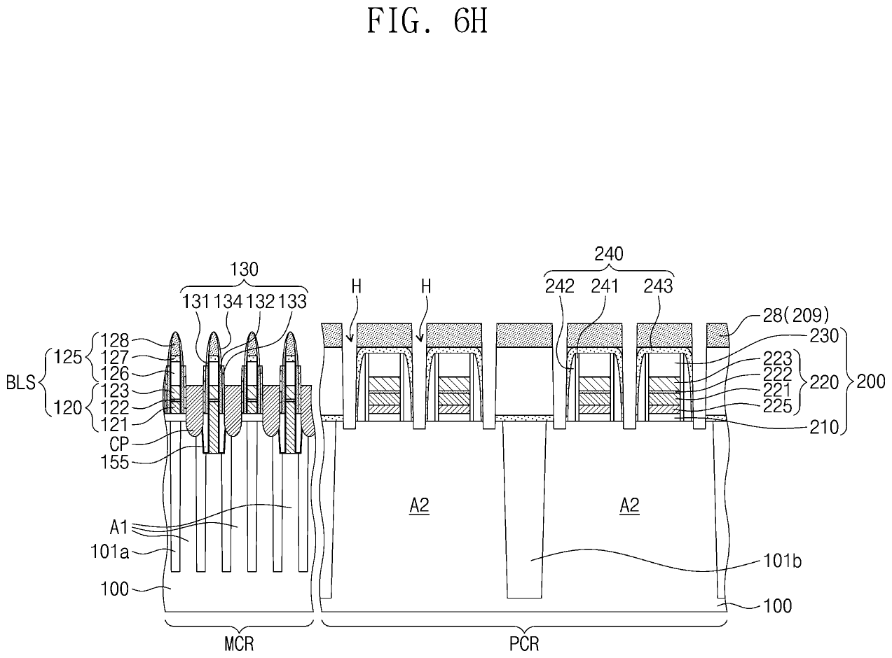

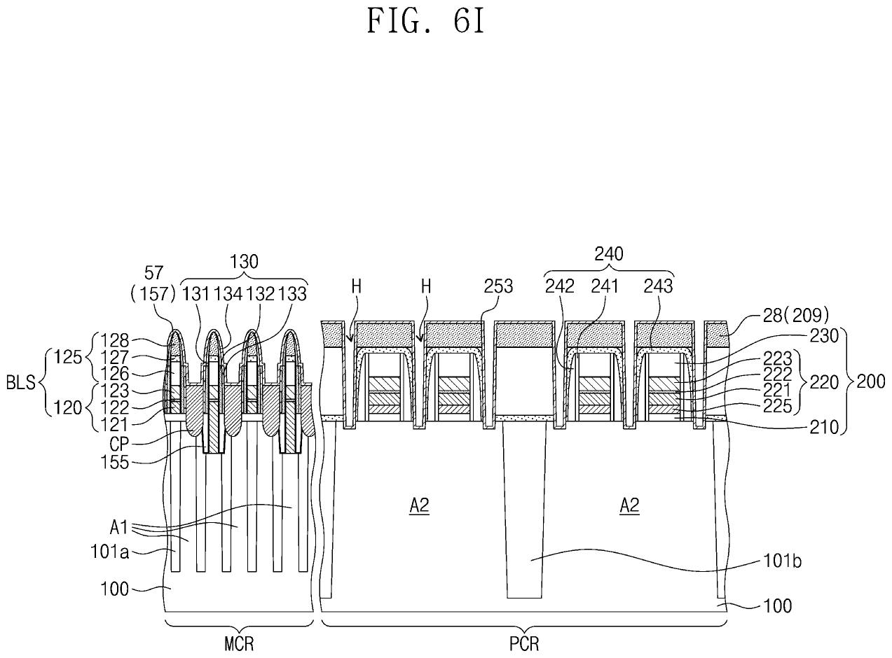

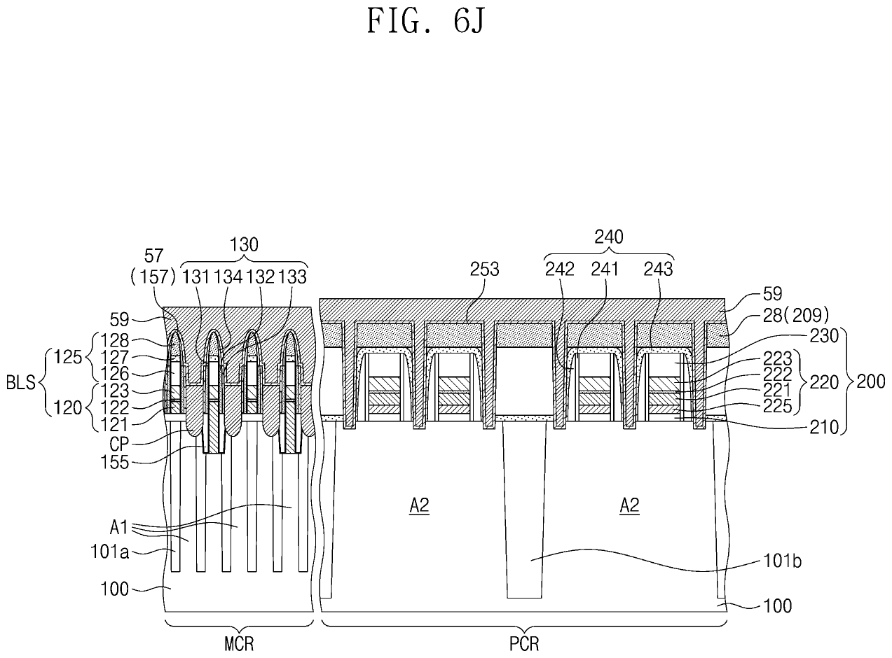

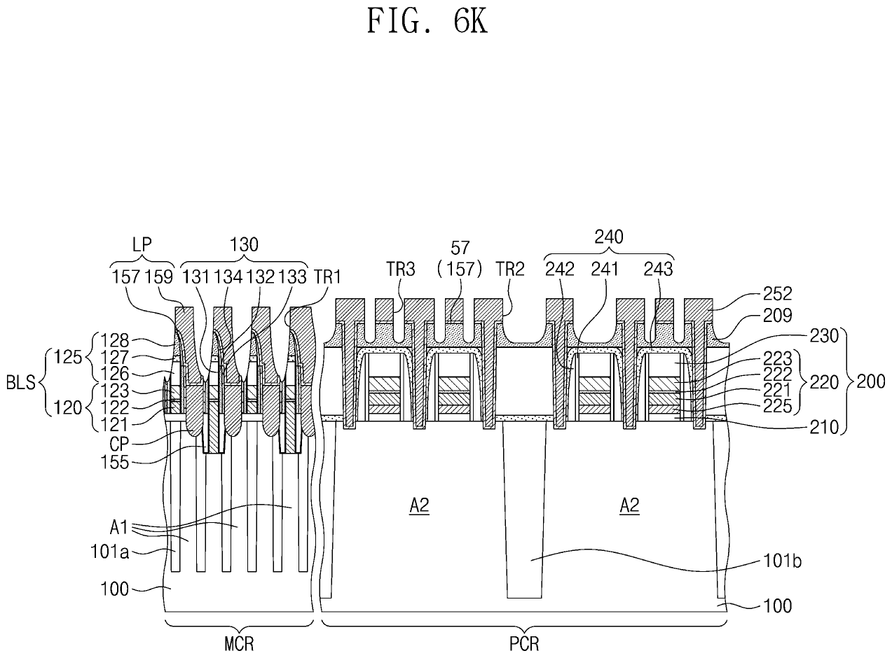

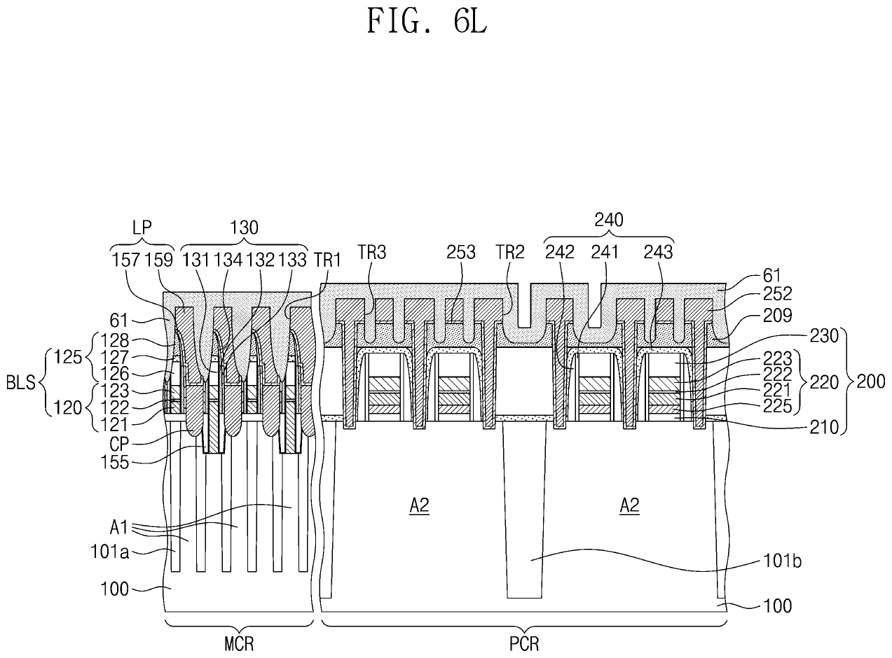

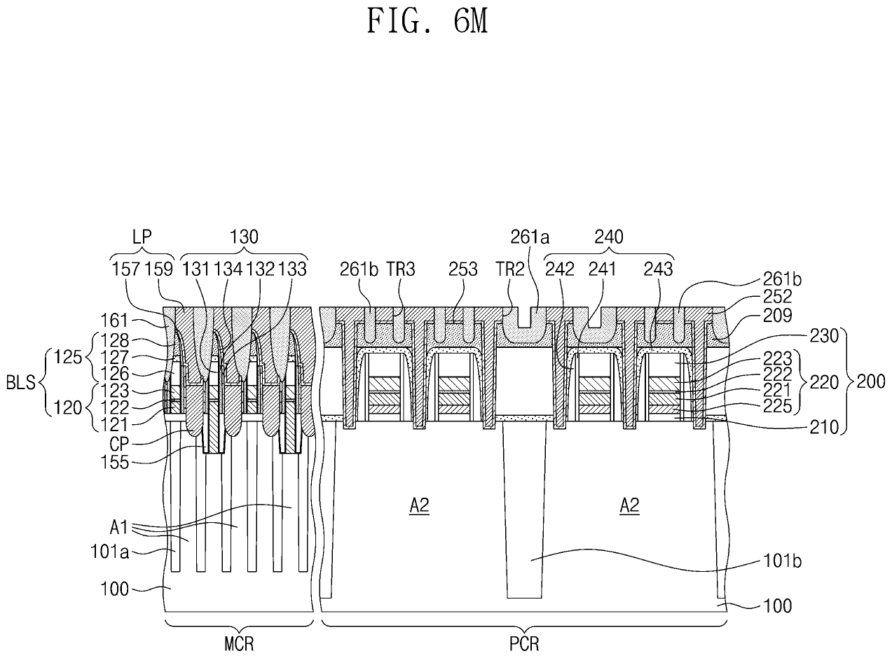

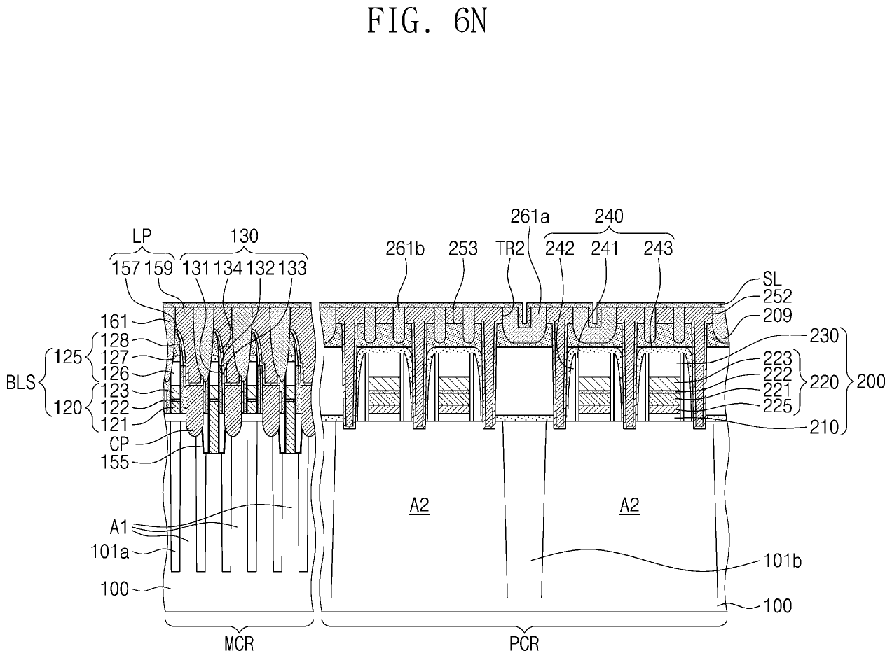

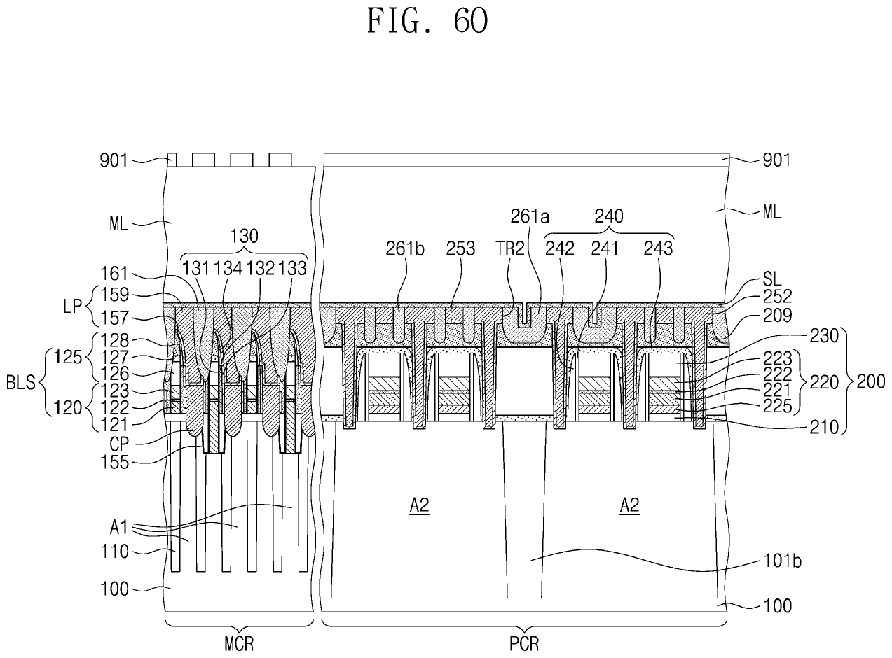

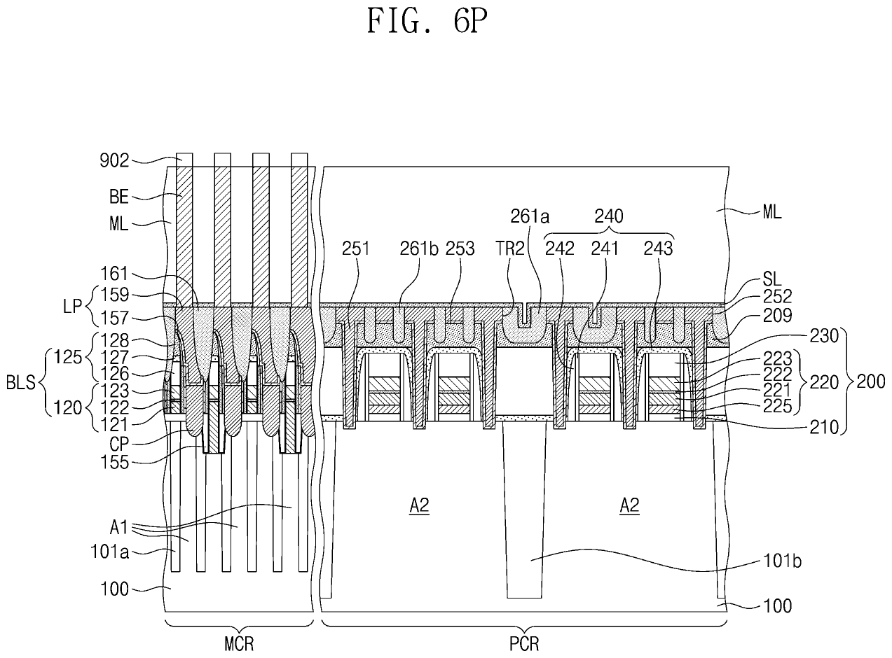

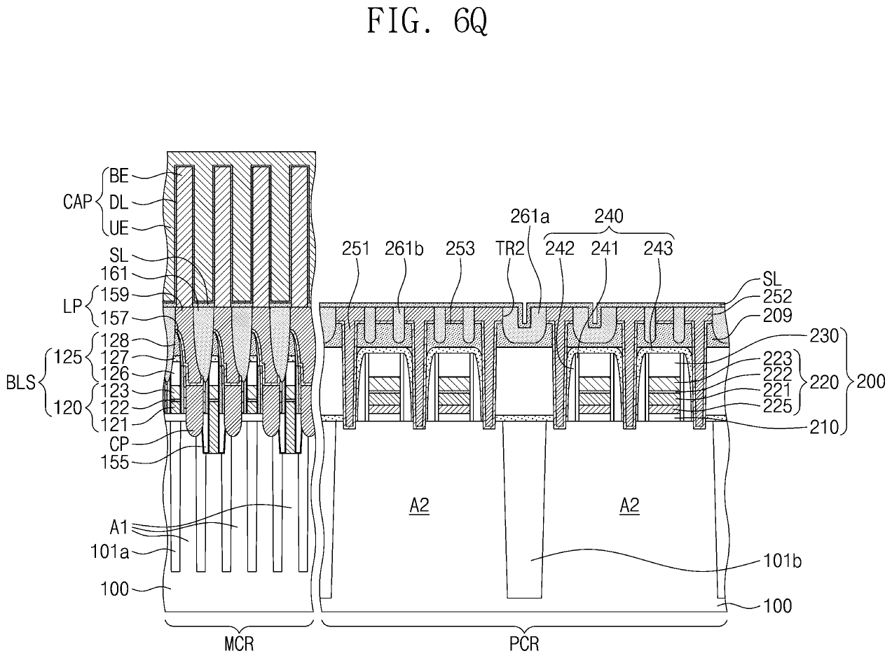

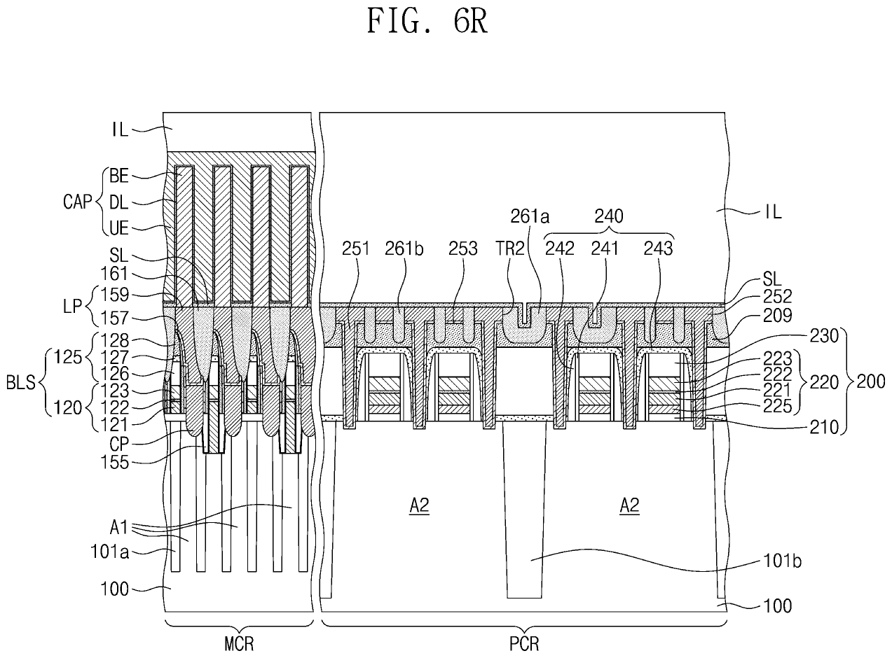

A spacer structure 130 may be provided between the bit line structures BLS and the lower contact CP. The spacer structure 130 may extend along the side surfaces of the bit line structures BLS and in the first direction D1. The spacer structure 130 may include a first spacer 131, a second spacer 132, a third spacer 133, and a fourth spacer 134. (Refer also FIG. 6O) The first spacer 131 may be directly on the side surface of the bit line structure BLS. The second spacer 132 may be between the first spacer 131 and the lower contact CP. The third spacer 133 may be between the second spacer 132 and the lower contact CP. The second spacer 132 may be placed between the first and third spacers 131 and 133. The first and third spacers 131 and 133 may be formed of or include an insulating material having an etch selectivity with respect to the lower insulating layer 110.

The second spacer 132 may be formed of or include an insulating material whose dielectric constant is lower than the first and third spacers 131 and 133. As an example, the first and third spacers 131 and 133 may be formed of or include silicon nitride, and the second spacer 132 may be formed of or include silicon oxide. As another example, the second spacer 132 may include air. That is, the second spacer 132 may be an air spacer which is defined between the side surfaces of the first and third spacers 131 and 133. The fourth spacer 134 may be on a top surface of the second spacer 132 and on a side surface of the first spacer 131. The fourth spacer 134 may at least partially enclose a lower portion of the landing pad LP. The fourth spacer 134 may have a ring shape, when viewed in a plan view.

An insulating pattern 161 may be in and at least partially fill a space between the landing pads LP. The insulating pattern 161 may at least partially enclose side surfaces LPs of the landing pads LP. The insulating pattern 161 may be in a first trench TR1 defined between side surfaces of the landing pads LP, as shown in FIG. 3. The first trench TR1 may be a node separation trench that is configured to electrically separate the landing pads LP from each other. The landing pads LP may be spaced apart from each other with the first trench TR1 interposed therebetween. The first trench TR1 may have an inner side surface, which is defined by surfaces of the landing pads LP, the bit line capping patterns 125, and the spacer structure 130. For example, the insulating pattern 161 may be formed of or include silicon nitride.

Capacitors CAP may be provided on the landing pads LP. The capacitors CAP may be electrically connected to the landing pads LP, respectively. Each of the capacitors CAP may include a bottom electrode BE, a top electrode UE, and a high-k dielectric layer DL therebetween. Each of the bottom and top electrodes BE and UE may be formed of or include one or more materials including, but not limited to, titanium, tantalum, tungsten, copper, and/or aluminum.

The bottom electrode BE and the top electrode UE may be formed of or include one or more materials including, but not limited to, doped silicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or combinations thereof. The high-k dielectric layer DL may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or any combination thereof.

An insulating layer IL may be on the capacitor CAP, and a first connection via VA1 may penetrate the insulating layer IL and may be connected to the capacitor CAP.

a gate stack 200 may be on the peripheral region PCR of the substrate 100. The gate stack 200 may extend in a direction parallel to the top surface of the substrate 100. In an embodiment, the gate stack 200 may be configured to have a bar shape. The gate stack 200 may be on a second active region A2, which is formed in an upper portion of the substrate 100. The second active region A2 may be an impurity region, which is doped with n- or p-type impurities, and may be defined by a second device isolation layer 101b.

Impurity regions 201 may be formed in an upper portion of the substrate 100. The impurity regions 201 may contain impurities different from the impurities in the second active region A2 and may have a conductivity type different from the second active region A2. The impurity regions 201 may include a pair of source and drain regions, which are electrically connected to or disconnected from each other by a voltage applied to the gate stack 200. The impurity regions 201 may be spaced apart from each other with the gate stack 200 interposed therebetween. The impurity regions 201 may be respectively placed near opposite side surfaces of the gate stack 200. As an example, the gate stack 200 and the impurity regions 201 may constitute a PMOS transistor, and the impurity regions 201 may be p-type impurity regions. For example, the impurity regions 201 may contain one or more materials including, but not limited to, boron (B), aluminum (Al), gallium (Ga), and/or indium (In). As another example, the gate stack 200 and the impurity regions 201 may constitute an NMOS transistor, and the impurity regions 201 may be n-type impurity regions. The impurity regions 201 may contain one or more materials including, but not limited to phosphorus (P), arsenic (As), and/or antimony (Sb).

The gate stack 200 may include a gate insulating layer 210, a gate electrode 220, and a gate capping pattern 230. The gate insulating layer 210 may be interposed between the top surface of the substrate 100 and the gate electrode 220. The gate capping pattern 230 may be on a top surface of the gate electrode 220.

The gate insulating layer 210 may be formed of or include one or more dielectric materials. In an embodiment, the gate insulating layer 210 may include a first dielectric layer and a second dielectric layer on the first dielectric layer. The first dielectric layer may have a dielectric constant lower than the second dielectric layer. For example, the first dielectric layer may include a silicon oxide layer and/or a silicon oxynitride layer. The second dielectric layer may be formed of or include one or more high-k dielectric materials whose dielectric constants are higher than silicon oxide and/or silicon oxynitride. For example, the second dielectric layer may be formed of or include oxides, nitrides, silicides, and/or oxynitrides which contain one of hafnium (Hf), aluminum (Al), zirconium (Zr), and/or lanthanum (La).

The gate electrode 220 may include a work-function adjusting layer 225, a first conductive layer 221, a second conductive layer 222, and a third conductive layer 223, which are sequentially stacked. The work-function adjusting layer 225 may be configured to control a threshold voltage of a transistor. In an embodiment, the work-function adjusting layer 225 may be thicker than the gate insulating layer 210. The work-function adjusting layer 225 may include a p-type metal layer and/or an n-type metal layer. The work-function adjusting layer 225 may be formed of or include one or more materials including, but not limited to, Ti, Ta, Al, Ni, Co, La, Pd, Nb, Mo, Hf, Ir, Ru, Pt, Yb, Dy, Er, Pd, TiAl, HfSiMo, TiN, WN,TaN, RuN, MoN, TiAlN, TaC, TiC, and/or TaC. In an embodiment, the work-function adjusting layer 225 may further include La/TiN, Mg/TiN, and/or Sr/TiN.

The first conductive layer 221 may be formed of or include one or more doped semiconductor materials. For example, the first conductive layer 221 may be formed of or include doped poly silicon. In an embodiment, the first conductive layer 221 may be doped with p-type dopants.

The second conductive layer 222 may be formed between the first and third conductive layers 221 and 223. The second conductive layer 222 may be thinner than the first and third conductive layers 221 and 223. The second conductive layer 222 may include a silicide layer, which is formed at an interface between the first and third conductive layers 221 and 223. The second conductive layer 222 may be formed of or include one or more materials including, but not limited to, titanium silicide, cobalt silicide, nickel silicide, tungsten silicide, platinum silicide, and/or molybdenum silicide. The third conductive layer 223 may be formed of or include one or more metallic materials. For example, the third conductive layer 223 may be formed of or include W, Ti, and/or Ta.

The gate capping pattern 230 may be disposed on the top surface of the gate electrode 220. The gate capping pattern 230 may be formed to be on and at least partially cover a top surface of the third conductive layer 223 and thereby to protect the gate electrode 220. The gate capping pattern 230 may be formed of or include one or more insulating materials. For example, the gate capping pattern 230 may be formed of or include silicon nitride.

A gate spacer structure 240 may be on the side surface of the gate stack 200. The gate spacer structure 240 may include a first gate spacer 241, a second gate spacer 242, and a third gate spacer 243.

The first gate spacer 241 may be on the side surface of the gate stack 200. The first gate spacer 241 may vertically extend along the side surfaces of the gate stack 200. The first gate spacer 241 may have a lower oxygen content lower than the second gate spacer 242. The first gate spacer 241 may have a first dielectric constant of 6.5 to 7.5. The first gate spacer 241 may be formed of or include a material having an etch selectivity with respect to the second gate spacer 242. For example, the first gate spacer 241 may be formed of or include silicon nitride. A top surface of the first gate spacer 241 may be coplanar with a top surface of the gate capping pattern 230. The first gate spacer 241 may be directly on a side surface of the gate electrode 220 and a side surface of the gate capping pattern 230.

The second gate spacer 242 may be on the first gate spacer 241. The second gate spacer 242 may have a width greater than the first gate spacer 241. The width of the second gate spacer 242 may decrease with increasing distance from the top surface of the substrate 100. The second gate spacer 242 may be formed of or include, for example, silicon oxide.

The third gate spacer 243 may be on the second gate spacer 242. The third gate spacer 243 may extend to a region on a top surface of the gate stack 200 to at least partially cover the top surface of the first gate spacer 241 and the top surface of the gate capping pattern 230. In an embodiment, the third gate spacer 243 may extend to a region on the top surface of the substrate 100.

A first interlayer insulating layer 207 may be formed on the substrate 100. The first interlayer insulating layer 207 may be provided to at least partially cover side surfaces of the gate spacer structure 240, but not a top surface of the gate spacer structure 240 so that the top surface of the gate spacer structure 240 remains free of the interlayer insulating layer 207. A top surface of the first interlayer insulating layer 207 may be coplanar with a top surface of the third gate spacer 243. The first interlayer insulating layer 207 may include a HDP oxide layer or a silicon oxide layer, which is formed by a flowable CVD (FCVD) method. A second interlayer insulating layer 209 may be formed on the first interlayer insulating layer 207. A bottom surface of the second interlayer insulating layer 209 may at least partially cover the top surface of the third gate spacer 243. The second interlayer insulating layer 209 may be formed of or include silicon nitride.

A peripheral circuit interconnection line 252 may be formed on the second interlayer insulating layer 209. The peripheral circuit interconnection line 252 may be coupled to the impurity region 201 through a peripheral contact 251. The peripheral contact 251 and the peripheral circuit interconnection line 252 may be formed of or include one or more materials including, but not limited to, copper (Cu), tungsten (W) and aluminum (Al), tantalum (Ta), and/or titanium (Ti). The peripheral contact 251 may be provided to penetrate the first interlayer insulating layer 207 and the second interlayer insulating layer 209 and may be connected to the substrate 100. In an embodiment, a bottom end of the peripheral contact 251 may be located at a level lower than the top surface of the substrate 100 as shown in the cross-sectional view of FIG. 3. The peripheral contact 251 may electrically connect the peripheral circuit interconnection line 252 to the impurity regions 201.

A contact barrier layer 253 may at least partially cover the peripheral circuit interconnection line 252 and the peripheral contact 251. The contact barrier layer 253 may be between a bottom surface of the peripheral circuit interconnection line 252 and the second interlayer insulating layer 209. The contact barrier layer 253 may be on side and bottom surfaces of the peripheral contact 251. The contact barrier layer 253 may include metal nitride. The contact barrier layer 253 may be formed of or include one or more materials including, but not limited to, titanium nitride (TiN), tantalum nitride (TaN), and/or tungsten nitride (WN).

A second trench TR2 and a third trench TR3 may be formed between the peripheral circuit interconnection lines 252. The second trench TR2 and the third trench TR3 may be formed between side surfaces of the peripheral circuit interconnection lines 252 to penetrate the second interlayer insulating layer 209. A bottom of the second trench TR2 may be located at a level higher than the top surface of the gate capping pattern 230 as shown in the cross-sectional view of FIG. 3. A bottom of the third trench TR3 may be located at a level higher than the top surface of the gate capping pattern 230 as shown in the cross-sectional view of FIG. 3. In an embodiment, a bottom of the third trench TR3 may be located at a level lower than the top surface of the gate capping pattern 230 as shown in the cross-sectional view of FIG. 3.

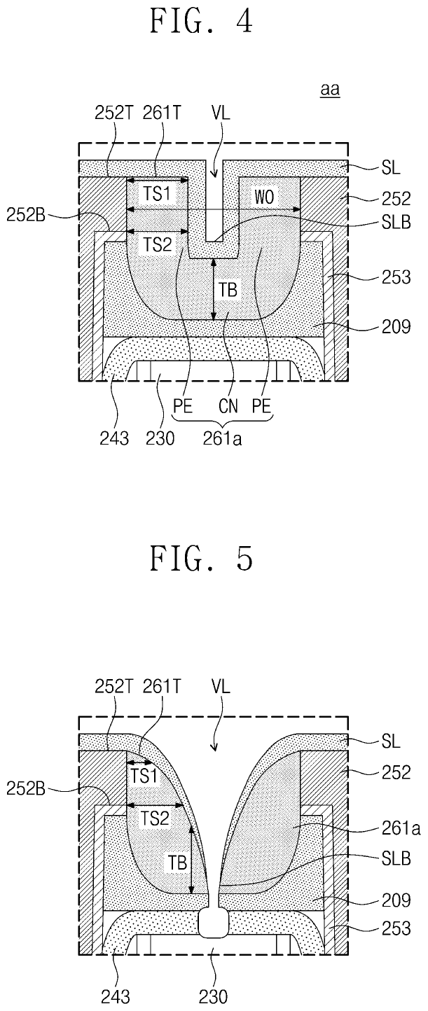

A width of the second trench TR2 may be greater than that of the third trench TR3, when measured in a first direction parallel to the substrate 100. As an example, the width (WO of FIG. 4) of the second trench TR2 in the first direction may range from about 80 nm to about 100 nm. The width of the third trench TR3 in the first direction may be greater than about 0 nm and may be less than or equal to about 20 nm.

In an embodiment, the second trench TR2 may vertically overlap the gate stack 200 as shown in FIG. 3 (e.g., see a portion ‘aa’) or vertically overlap the second device isolation layer 101b between the gate stacks 200.

A first interconnection insulating pattern 261a may be in and at least partially fill a portion of the second trench TR2, and a second interconnection insulating pattern 261b may be in and at least partially or fully fill the third trench TR3. In an embodiment, the first and second interconnection insulating patterns 261a and 261b may be formed of or include silicon nitride. The first interconnection insulating pattern 261a will be described in more detail below.

An etch stop layer SL may at least partially cover the insulating pattern 161, the first interconnection insulating pattern 261a, the second interconnection insulating pattern 261b, and the peripheral circuit interconnection lines 252. The insulating layer IL may be on the etch stop layer SL. A second connection via VA2 may penetrate the insulating layer IL and the etch stop layer SL and may be connected to the peripheral circuit interconnection lines 252.

FIG. 4 is an enlarged sectional view illustrating the portion ‘aa’ of FIG. 3.

Referring to FIGS. 3 and 4, the first interconnection insulating pattern 261a may have a “U” shape. In detail, the first interconnection insulating pattern 261a may include a pair of vertical portions PE, which are spaced apart from each other in the first direction, and a connecting portion CN, which connects them to each other. One of the vertical portions PE of the first interconnection insulating pattern 261a may have a first side surface, which is in physical contact with the side surface of the peripheral circuit interconnection line 252, and a second side surface, which is spaced apart from the side surface of the peripheral circuit interconnection line 252. The second side surface of the vertical portion PE of the first interconnection insulating pattern 261a may have substantially the same slope as the side surface of the peripheral circuit interconnection line 252. For example, in the case where a slope of the side surface of the peripheral circuit interconnection line 252 relative to the top surface of the substrate 100 is 90° or is close to 90°, a slope of the second side surface of the vertical portion PE of the first interconnection insulating pattern 261a may be 90° or may be close to 90°.

A top surface 261T of the vertical portion PE of the first interconnection insulating pattern 261a may be coplanar with a top surface 252T of the peripheral circuit interconnection line 252 which is in physical contact with or adjacent to the vertical portion PE. This may result from a planarization process performed on the first interconnection insulating pattern 261a and the peripheral circuit interconnection line 252, as will be described below.

The vertical portion PE of the first interconnection insulating pattern 261a may have a first thickness TS1, when measured in a first direction at the same level as the top surface 252T of the peripheral circuit interconnection line 252 adjacent thereto. The vertical portion PE of the first interconnection insulating pattern 261a may have a second thickness TS2, when measured in the first direction at the same level as a bottom surface 252B of the peripheral circuit interconnection line 252 adjacent thereto. The first thickness TS1 may be substantially equal to the second thickness TS2.

The connecting portion CN of the first interconnection insulating pattern 261a may have a third thickness TB in a direction perpendicular to the top surface of the substrate 100. The third thickness TB may be equal to or greater than the first and second thicknesses TS1 and TS2.

The etch stop layer SL may be on and at least partially cover a top surface of the peripheral circuit interconnection line 252 and a top surface of the first interconnection insulating pattern 261a. The lowermost portion SLT of the etch stop layer SL may be located between top and bottom surfaces of the second interlayer insulating layer 209. The lowermost portion SLB of the etch stop layer SL may be located to be closer to a top surface of the second interlayer insulating layer 209 than to the bottom surface of the second interlayer insulating layer 209. A thickness of a portion of the etch stop layer SL, which is in physical contact with the vertical portion PE of the first interconnection insulating pattern 261a, may be substantially equal to a thickness of another portion of the etch stop layer SL, which is in physical contact with the connecting portion CN of the first interconnection insulating pattern 261a.

The etch stop layer SL may be provided to at least partially fill a space between the vertical portions PE of the first interconnection insulating pattern 261a. A space VL, which is not filled with the etch stop layer SL, may be at least partially filled with the insulating layer IL. In an embodiment, the etch stop layer SL may be provided to at least partially or fully fill the space between the vertical portions PE.

The first interconnection insulating pattern 261a, which vertically overlaps with the second device isolation layer 101b (e.g., see the portion aa’ of FIG. 3), may be configured to have the afore-described features of the first interconnection insulating pattern 261a.

Referring back to FIG. 3, a level of the top surface of the landing pad LP may be substantially the same as a level of the top surface of the peripheral circuit interconnection line 252. In addition, a level of a top surface of the insulating pattern 161 may be substantially the same as a level of the top surface of the first interconnection insulating pattern 261a and a level of the top surface of the second interconnection insulating pattern 261b.

According to an embodiment of the inventive concept, the first interconnection insulating pattern 261a may be formed to have a generally uniform thickness in the second trench TR2. This may be because the first interconnection insulating pattern 261a is formed by a planarization process, as will be described with reference to FIG. 6M. It may be possible to prevent or suppress a thickness of a portion of the connecting portion CN of the first interconnection insulating pattern 261a from being reduced during the planarization process. As a result, the etch stop layer SL may be stably provided on the connecting portion CN of the first interconnection insulating pattern 261a. Because the etch stop layer SL is conformally provided on the second interlayer insulating layer 209, it may be possible to prevent or reduce the likelihood of the gate stack 200 or the first interlayer insulating layer 207, which is located below the second interlayer insulating layer 209, from being damaged in an etching process to be described with reference to FIG. 6Q.

FIG. 5 is an enlarged sectional view illustrating a portion of a semiconductor device, which corresponds to the portion ‘aa’ of FIG. 3, according to a comparative example.

FIG. 5 illustrates a structure, in which an insulating pattern 261 is formed by an etching process, not by a planarization process described with reference to FIG. 6M. Unlike the structure illustrated in FIG. 3, the first interconnection insulating pattern 261a may not have a “U” shape. In the structure of FIG. 5, the first thickness TS1 of the first interconnection insulating pattern 261a in the first direction may be less than the second thickness TS2. In addition, the third thickness TB may decrease in a direction toward the center of the first interconnection insulating pattern 261a, and a hole may be formed to penetrate a center portion of the first interconnection insulating pattern 261a. Thus, the gate stack 200 or the first interlayer insulating layer 207 below the second interlayer insulating layer 209 may be damaged. As a depth increases, a bottom portion of the second interlayer insulating layer 209 may not be covered with the etch stop layer SL. In this case, the gate stack 200 or the first interlayer insulating layer 207 below the second interlayer insulating layer 209 may be damaged in an etching process to be described with reference to FIG. 6Q.

FIGS. 6A to 6R are sectional views, which are taken along the lines A-A′ and C-C′ of FIG. 2 to illustrate a method of fabricating a semiconductor device according to an embodiment of the inventive concept.

Referring to FIG. 6A, the first and second device isolation layers 101a and 101b may be formed in the substrate 100 to define the first active region A1 and the second active region A2. The first and second device isolation layers 101a and 101b may be formed by forming trenches in an upper portion of the substrate 100 and at least partially filling the trenches with an insulating material.

The lower insulating layer 110 may be formed on the cell region MCR of the substrate 100. The lower insulating layer 110 may include a single insulating layer or a plurality of insulating layers. The lower insulating layer 110 may include, for example, a silicon oxide layer, a silicon nitride layer, and/or a silicon oxynitride layer.

Next, the substrate 100 and the lower insulating layer 110 may be patterned to form recess regions exposing cell impurity regions, respectively. Each of the recess regions may have, for example, an elliptical shape, when viewed in a plan view. In addition, the recess regions may be arranged in a zigzag or honeycomb shape, when viewed in a plan view.

A preliminary gate insulating layer 210p and a preliminary work-function adjusting layer 225p may be formed on the peripheral region PCR of the substrate 100. The preliminary gate insulating layer 210p and the preliminary work-function adjusting layer 225p may not be formed on the cell region MCR of the substrate 100.

Referring to FIG. 6B, a first preliminary conductive layer 21, a second preliminary conductive layer 22, a third preliminary conductive layer 23, and a first preliminary insulating layer 26 may be formed on the substrate 100. The first preliminary conductive layer 21 may be formed of or include a doped semiconductor material. The first preliminary conductive layer 21 may be formed of or include, for example, polysilicon. The third preliminary conductive layer 23 may be formed of or include one or more metallic materials (e.g., W, Ti, and Ta). The first preliminary conductive layer 21 and the third preliminary conductive layer 23 may be formed by an ALD or PVD process. The second preliminary conductive layer 22 may be formed of or include silicide and may be formed as a result of reaction between a top surface of the first preliminary conductive layer 21 and a bottom surface of the third preliminary conductive layer 23. The first preliminary insulating layer 26 may be formed of or include silicon nitride and may be formed using one of ALD, CVD, and PVD processes.

Referring to FIG. 6C, a patterning process may be performed to form the gate stack 200 on the peripheral region PCR. Thereafter, the first gate spacer 241 and the second gate spacer 242 may be formed on the side surface of the gate stack 200.

Referring to FIG. 6D, a second preliminary insulating layer 27 and a third preliminary insulating layer 28 may be formed on the substrate 100. The second preliminary insulating layer 27 and the third preliminary insulating layer 28 may be sequentially formed on the cell region MCR to at least partially cover the first preliminary insulating layer 26. The second preliminary insulating layer 27 may be formed on the peripheral region PCR to at least partially cover the top surface of the substrate 100, the side surface of the second gate spacer 242, and the top surface of the gate stack 200. The third gate spacer 243 may be formed from the second preliminary insulating layer 27 on the peripheral region PCR. The first interlayer insulating layer 207 may be formed before forming the third preliminary insulating layer 28 on the peripheral region PCR. The first interlayer insulating layer 207 may at least partially cover the third gate spacer 243. The first interlayer insulating layer 207 may be formed to have a top surface, which is located at the same level as the top surface of the third gate spacer 243. The third preliminary insulating layer 28 may be formed on the first interlayer insulating layer 207. The second interlayer insulating layer 209 may be formed from the third preliminary insulating layer 28 on the peripheral region PCR.

Referring to FIG. 6E, a patterning process may be performed on the cell region MCR of the substrate 100 to form the bit line structure BLS. During the patterning process, the peripheral region PCR of the substrate 100 may be veiled by a mask pattern.

Referring to FIG. 6F, the first spacer 131, the second spacer 132, and the third spacer 133 may be formed on the cell region MCR to sequentially at least partially cover the side surface of the bit line structure BLS. In an embodiment, the bit line contact spacer 155 may be formed on a lower side surface of the bit line structure BLS, before the formation of the second and third spacers 132 and 133.

Referring to FIG. 6G, preliminary lower contacts CPp may be formed between the side surfaces of the bit line structure BLS. Next, an etching process may be performed to partially remove upper portions of the first, second, and third spacers 131, 132, and 133. The etching process may be performed until top surfaces of the first, second, and third spacers 131, 132, and 133 are located at a level similar to the top surfaces of the preliminary lower contacts CPp.

Referring to FIG. 6H, the fourth spacer 134 may be formed to at least partially cover an upper side surface of the first spacer 131. Thereafter, the lower contacts CP may be formed by partially removing upper portions of the preliminary lower contacts CPp. The lower contacts CP may be formed to have top surfaces that are located at a level lower than the top surface of the second spacer 132 and the top surface of the preliminary lower contacts CPp. The first to fourth spacers 131, 132, 133, and 134 may constitute the spacer structure 130.

Next, contact holes H may be formed on the peripheral region PCR of the substrate 100 to vertically penetrate the first interlayer insulating layer 207 and the second interlayer insulating layer 209. An upper portion of the substrate 100 may be partially removed during the formation of the contact holes H. The contact holes H may have bottom surfaces, which are located at a level lower the top surface of the substrate 100 as shown in FIG. 6H.

Referring to FIG. 6I, a deposition process may be performed to form a preliminary barrier layer 57 on the substrate 100. The preliminary barrier layer 57 may at least partially cover the top surface of the lower contacts CP, the side surfaces of the spacer structure 130, and the top surfaces of the bit line structure BLS, on the cell array region MCR. The preliminary barrier layer 57 may at least partially cover the top surface of the second interlayer insulating layer 209 and an inner surface of the contact hole H, on the peripheral region PCR.

Referring to FIG. 6J, a metal layer 59 may be formed on the preliminary barrier layer 57. On the cell region MCR, the metal layer 59 may at least partially fill a space between the spacer structures 130 and may extend to a region on the top surface of the bit line structure BLS. The preliminary barrier layer 57 may form the barrier layer 157 on the cell region MCR and may form the contact barrier layer 253 on the peripheral region PCR.

Referring to FIG. 6K, a patterning process on the metal layer 59 may be performed to form the first trench TR1 and the pad metal pattern 159 on the cell region MCR, and as a result, the landing pad LP may be formed on the cell region MCR. In an embodiment, the patterning process on the metal layer 59 may be performed to form the second trench TR2 and the third trench TR3 on the peripheral region PCR, and as a result, the peripheral circuit interconnection line 252 may be formed on the peripheral region PCR.

Referring to FIG. 6L, a deposition process may be performed to form a preliminary insulating pattern 61 on the substrate 100. In an embodiment, the deposition process may be a chemical vapor deposition (CVD) process. On the cell region MCR, the preliminary insulating pattern 61 may be formed to at least partially fill the first trench TR1 and to at least partially cover the top surface of the landing pad LP. In addition, on the peripheral region PCR, the preliminary insulating pattern 61 may be formed to at least partially fill the second trench TR2 and the third trench TR3 and to at least partially cover the top surface of the peripheral circuit interconnection line 252. The first and third trenches TR1 and TR3 may be at least partially or fully filled with the preliminary insulating pattern 61, whereas the second trench TR2 may be at least partially filled with the preliminary insulating pattern 61.

Referring to FIG. 6M, a planarization process may be performed on the preliminary insulating pattern 61. In an embodiment, the planarization process may be a chemical-mechanical polishing process (CMP). The planarization process may be performed on both of the cell region MCR and the peripheral region PCR. The planarization process may be performed to expose at least a portion of the top surface of the landing pad LP on the cell region MCR and the top surface of the peripheral circuit interconnection line 252.

As a result of the planarization process, the preliminary insulating pattern 61 on the cell region MCR may be patterned to form the insulating pattern 161. The top surface of the insulating pattern 161 may be located at substantially the same level as a top surface of the pad metal pattern 159. In addition, the preliminary insulating pattern 61 on the peripheral region PCR may be patterned to form the first and second insulating interconnection patterns 261a and 261b. The first and second insulating interconnection patterns 261a and 261b may have top surfaces, which are formed at substantially the same level as the top surfaces of the peripheral circuit interconnection lines 252. After the planarization process, a cleaning process may be additionally performed.

Referring to FIG. 6N, the etch stop layer SL may be formed on the substrate 100. The etch stop layer SL may be formed to conformally at least partially cover the top surface of the first interconnection insulating pattern 261a in the second trench TR2. In an embodiment, the etch stop layer SL may be formed to at least partially or fully fill the remaining space of the second trench TR2, which is not filled with the first interconnection insulating pattern 261a.

Referring to FIG. 6O, a molding member ML may be formed on the etch stop layer SL. The molding member ML may be formed of or include a material having an etch selectivity with respect to the etch stop layer SL. In an embodiment, the molding member ML may be formed of or include silicon oxide. A first mask 901 may be formed on the molding member ML to define a region, in which the bottom electrode BE will be formed.

Referring to FIG. 6P, an electrode hole at least partially exposing the landing pad LP may be formed by sequentially etching a portion of the molding member ML and the etch stop layer SL using the first mask 901 as an etch mask. A conductive material may be formed to at least partially fill the electrode hole, an etch-back or chemical-mechanical process may be performed on the conductive material to form the bottom electrode BE, and then, the first mask 901 may be removed. Thereafter, a second mask pattern 902 may be selectively formed on a region that overlaps with the bottom electrode BE.

Referring to FIG. 6Q, a remaining portion of the molding member ML may be etched using the second mask pattern 902 as an etch mask. Here, there may be the etch stop layer SL left on the cell region MCR and the peripheral region PCR. Thereafter, the high-k dielectric layer DL and the top electrode UE may be sequentially formed on the cell region MCR to form the capacitor CAP.

Referring to FIG. 6L, the insulating layer IL may be formed on the substrate 100. The insulating layer IL may at least partially cover the capacitor CAP.

Referring back to FIG. 2, holes may be formed on the cell region MCR and the peripheral region PCR to penetrate the insulating layer IL, and the first connection via VA1 and the second connection via VA2 may be formed to at least partially fill the holes.

According to an embodiment of the inventive concept, it may be possible to improve reliability of a semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including a cell region and a peripheral region;
a gate stack on the peripheral region;
an interlayer insulating layer on the gate stack;
peripheral circuit interconnection lines on the interlayer insulating layer; and
an interconnection insulating pattern between the peripheral circuit interconnection lines,
wherein the interconnection insulating pattern comprises a pair of vertical portions, which are spaced apart from each other in a first direction parallel to a top surface of the substrate, and a connecting portion, which connects the vertical portions to each other,
wherein each of the vertical portions of the interconnection insulating pattern has a first thickness in the first direction at a same level as top surfaces of the peripheral circuit interconnection lines and a second thickness in the first direction at a same level as bottom surfaces of the peripheral circuit interconnection lines, and
wherein the first thickness is substantially equal to the second thickness.

2. The semiconductor device of claim 1, wherein the vertical portion of the interconnection insulating pattern is in physical contact with one of the peripheral circuit interconnection lines adjacent thereto, and
wherein a top surface of the vertical portion of the interconnection insulating pattern is coplanar with the top surface of the one of the peripheral circuit interconnection lines.

3. The semiconductor device of claim 1, wherein the connecting portion has a third thickness in a direction perpendicular to the top surface of the substrate, and
wherein the third thickness is uniform in the first direction.

4. The semiconductor device of claim 3, wherein the third thickness is equal to or greater than the first thickness and the second thickness.

5. The semiconductor device of claim 1, wherein the vertical portion of the interconnection insulating pattern has a first side surface, which is in physical contact with one of the peripheral circuit interconnection lines adjacent thereto, and a second side surface, which is spaced apart from the first side surface in the first direction, and
wherein a slope of the second side surface is substantially equal to a slope of a side surface of the peripheral circuit interconnection line.

6. The semiconductor device of claim 1, further comprising an etch stop layer on the interconnection insulating pattern,
wherein a thickness of a portion of the etch stop layer, which is in physical contact with the vertical portion of the interconnection insulating pattern, is substantially equal to a thickness of another portion of the etch stop layer, which is in physical contact with the connecting portion of the interconnection insulating pattern.

7. The semiconductor device of claim 1, further comprising an etch stop layer on the interconnection insulating pattern,
wherein a lowermost portion of the etch stop layer is located at a level between top and bottom surfaces of the interlayer insulating layer, and
wherein the lowermost portion of the etch stop layer is located at a level that is closer to the top surface of the interlayer insulating layer than to the bottom surface of the interlayer insulating layer.

8. The semiconductor device of claim 1, wherein the insulating pattern has a width of about 80 nm to about 100 nm in the first direction.

9. The semiconductor device of claim 1, further comprising:
bit lines on the cell region of the substrate that extend in a second direction, which is parallel to the top surface of the substrate and crosses the first direction;
a lower contact coupled to the substrate, between two adjacent ones of the bit lines;
a landing pad on the lower contact; and
an insulating pattern at least partially enclosing a side surface of the landing pad,
wherein a level of a top surface of the insulating pattern is substantially equal to a level of a top surface of the interconnection insulating pattern.

10. The semiconductor device of claim 9, wherein a top surface of the landing pad is located at the same level as the top surfaces of the peripheral circuit interconnection lines.

11. A semiconductor device, comprising:
a substrate including a cell region and a peripheral region, the peripheral region comprising active regions and a device isolation layer defining the active regions,
gate stacks on the active region;
an interlayer insulating layer on the gate stack, the interlayer insulating layer comprising a first trench; and
peripheral circuit interconnection lines on the interlayer insulating layer and a first interconnection insulating pattern between the peripheral circuit interconnection lines,
wherein the first interconnection insulating pattern is in a portion of the first trench,
wherein the first interconnection insulating pattern overlaps the device isolation layer in a direction perpendicular to a top surface of the substrate, and
wherein the topmost surface of the first interconnection insulating pattern is coplanar with a top surface of one of the peripheral circuit interconnection lines adjacent thereto.

12. The semiconductor device of claim 11, wherein the first trench has a width in a first direction parallel to a top surface of the substrate, and
wherein the width ranges from about 80 nm to 100 nm.

13. The semiconductor device of claim 11, wherein the interlayer insulating layer further comprises a second trench,
wherein the semiconductor device further comprises a second interconnection insulating pattern between the peripheral circuit interconnection lines,
wherein the second interconnection insulating pattern is in the second trench,
wherein the second interconnection insulating pattern overlaps the gate stack in the direction perpendicular to the top surface of the substrate, and
wherein a width of the second trench is greater than about 0 nm and is less than or equal to about 20 nm.

14. The semiconductor device of claim 11, wherein the first interconnection insulating pattern comprises a pair of vertical portions, which are spaced apart from each other in a first direction parallel to the top surface of the substrate, and a connecting portion, which connects the vertical portions to each other,
wherein each of the vertical portions has a first thickness in the first direction,
wherein the connecting portion has a second thickness in the direction perpendicular to the top surface of the substrate, and
wherein the first thickness is substantially equal to the second thickness.

15. The semiconductor device of claim 14, wherein the vertical portion of the first interconnection insulating pattern has a first side surface, which is in physical contact with the peripheral circuit interconnection line adjacent thereto, and a second side surface, which is spaced apart from the first side surface in the first direction, and
wherein a slope of the second side surface is equal to a slope of a side surface of the peripheral circuit interconnection line.

16. The semiconductor device of claim 11, further comprising an etch stop layer on the first interconnection insulating pattern,
wherein a lowermost portion of the etch stop layer is located at a level between top and bottom surfaces of the interlayer insulating layer, and
wherein the lowermost portion of the etch stop layer is located at a level that is closer to the top surface of the interlayer insulating layer than to the bottom surface of the interlayer insulating layer.

17. The semiconductor device of claim 11, wherein the interlayer insulating layer further comprises a second trench,
wherein the semiconductor device further comprises a second interconnection insulating pattern between the peripheral circuit interconnection lines,
wherein the second interconnection insulating pattern is in the second trench,
wherein the second interconnection insulating pattern overlaps the gate stack in the direction perpendicular to the top surface of the substrate, and
wherein a width of the second trench ranges from about 80 nm to about 100 nm.

18. A semiconductor device, comprising:
a substrate including a cell region and a peripheral region, the cell region comprising first active regions and a first device isolation layer defining the first active regions, the peripheral region comprising second active regions and a second device isolation layer defining the second active region;
word lines that extend in a first direction to cross the first active regions;
bit line structures on the word lines that extend in a second direction perpendicular to the first direction;
spacer structures on side surfaces of the bit line structures;
a lower contact between the spacer structures and connected to the first active region;
a landing pad on the lower contact that extends to a region on top surfaces of the bit line structures, the landing pad comprising a pad metal pattern and a barrier layer between the pad metal pattern and the lower contact;
an insulating pattern at least partially enclosing a side surface of the landing pad, a top surface of the insulating pattern being coplanar with the landing pad;
a capacitor on a top surface of the landing pad;
gate stacks on the second active region;
gate spacer structures on side surfaces of each of the gate stacks;
a peripheral contact between the gate spacer structures and connected to the second active region;
a first interlayer insulating layer on and at least partially covering side surfaces of the gate spacer structures while top surfaces of the gate spacer structures remain free of the first interlayer insulating layer;
a second interlayer insulating layer on the gate stack and the first interlayer insulating layer;
peripheral circuit interconnection lines, which are on the first interlayer insulating layer, and each of which is connected to the peripheral contact; and
an interconnection insulating pattern between the peripheral circuit interconnection lines,
wherein the interconnection insulating pattern comprises a pair of vertical portions, which are spaced apart from each other in a first direction parallel to a top surface of the substrate, and a connecting portion, which connects the vertical portions to each other,
wherein each of the vertical portions of the interconnection insulating pattern has a first thickness at a same level as top surfaces of the peripheral circuit interconnection lines and a second thickness at a same level as bottom surfaces of the peripheral circuit interconnection lines,
wherein the connecting portion has a third thickness in a direction perpendicular to the top surface of the substrate, and
wherein the third thickness is equal to or greater than the first thickness and the second thickness.

19. The semiconductor device of claim 18, further comprising an etch stop layer on the interconnection insulating pattern,
wherein a lowermost portion of the etch stop layer is located at a level between top and bottom surfaces of the interlayer insulating layer, and
wherein the lowermost portion of the etch stop layer is located at a level that is closer to the top surface of the interlayer insulating layer than to the bottom surface of the interlayer insulating layer.

20. The semiconductor device of claim 18, wherein a top surface of the vertical portion of the interconnection insulating pattern is coplanar with the top surface of one of the peripheral circuit interconnection lines adjacent thereto.
